(19) United States
(12) Patent Application Publication
(10) Pub. No.: US 2025/0140743 A1
(43) Pub. Date: May 1, 2025

(54) CHIP STACKING STRUCTURE

(71) Applicant: Taiwan Semiconductor Manufacturing Company, Ltd., Hsinchu (TW)

(72) Inventors: Sheng-An Kuo, Hsinchu (TW); Chao-Wen Shih, Hsinchu County (TW); Kuo-Chiang Ting, Hsinchu City (TW); Yen-Ming Chen, Hsin-Chu County (TW)

(73) Assignee: Taiwan Semiconductor Manufacturing Company, Ltd., Hsinchu (TW)

(21) Appl. No.: 18/499,235

(22) Filed: Nov. 1, 2023

(51) Int. Cl. H01L 25/065; H01L 23/00; H01L 23/31; H01L 23/48; H01L 23/522; H01L 23/538

(52) U.S. Cl. CPC H01L 25/0652; H01L 23/3157; H01L 23/481; H01L 23/5226; H01L 23/5381; H01L 24/08; H01L 2224/08145

(57) ABSTRACT

A structure including a first semiconductor die, second semiconductor dies, a bridge die, and a gap filling material is provided. The first semiconductor die includes integrated circuit regions. The second semiconductor dies are disposed over and electrically connected to the first semiconductor die. The bridge die is disposed over and electrically connected to the first semiconductor die, and the integrated circuit regions are electrically connected to each other through the bridge die. The gap filling material is disposed on the first semiconductor die to laterally encapsulate the bridge die and the second semiconductor dies.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor wafer. The individual dies are singulated by sawing the integrated circuits along a scribe line. The individual dies are then packaged separately, in multi-chip modules, or in other types of packaging, for example.

The semiconductor industry continues to improve the integration density of various electronic components (e.g., transistors, diodes, resistors, capacitors, etc.) by continual reductions in minimum feature size, which allow more components to be integrated into a given area. These smaller electronic components such as integrated circuit dies may also require smaller packages that utilize less area than packages of the past, in some applications.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A through 1L are cross-sectional views schematically illustrating a process flow for fabricating chip stacking structures in accordance with some embodiments of the present disclosure.

FIGS. 2A through 2I are cross-sectional views schematically illustrating a process flow for fabricating a Package-on-Package (POP) structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Packages and the methods of forming the same are provided in accordance with various exemplary embodiments. The intermediate stages of forming the packages are illustrated. The variations of the embodiments are discussed. Throughout the various views and illustrative embodiments, like reference numbers are used to designate like elements.

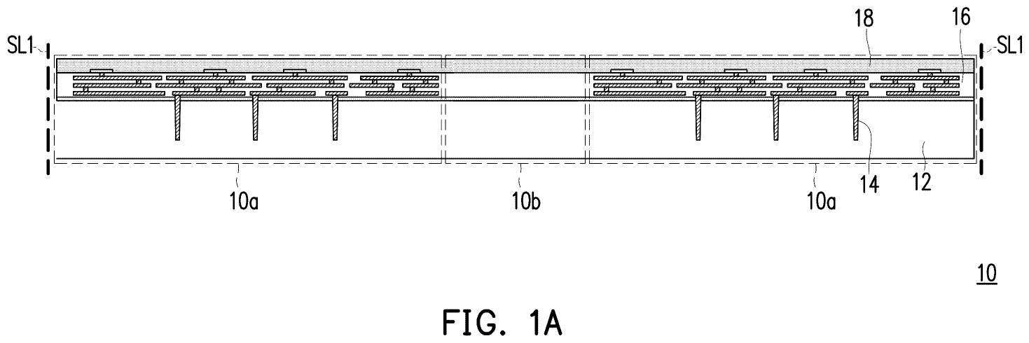

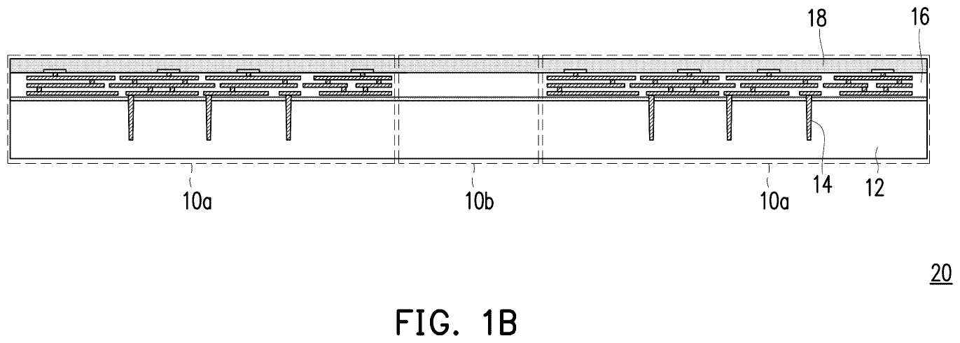

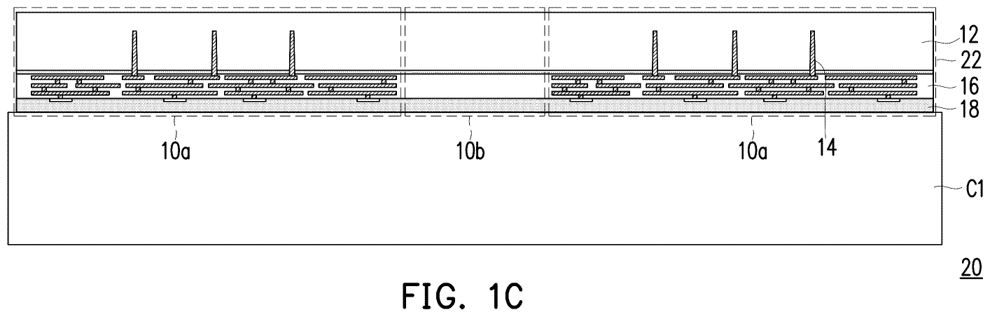

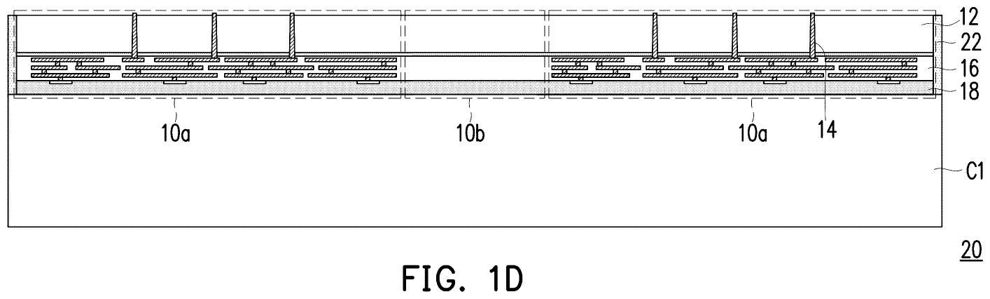

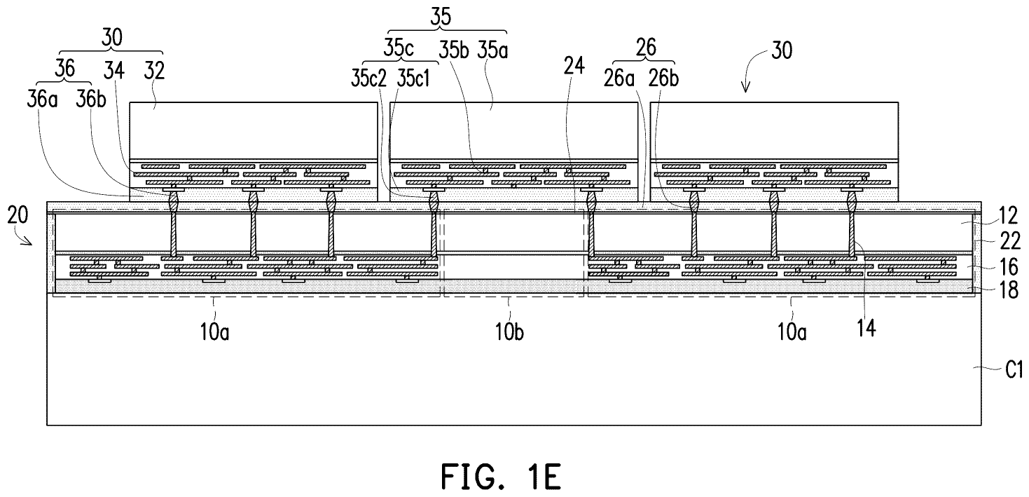

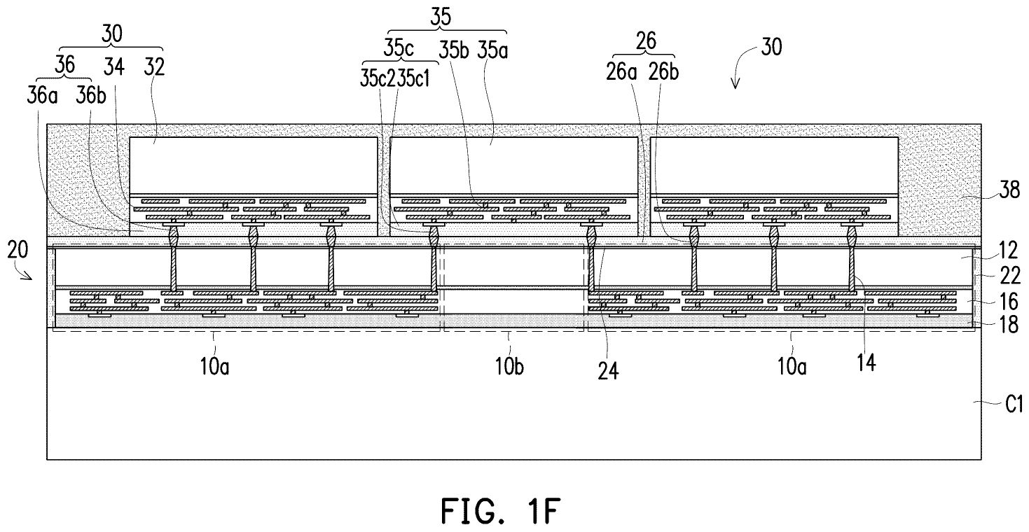

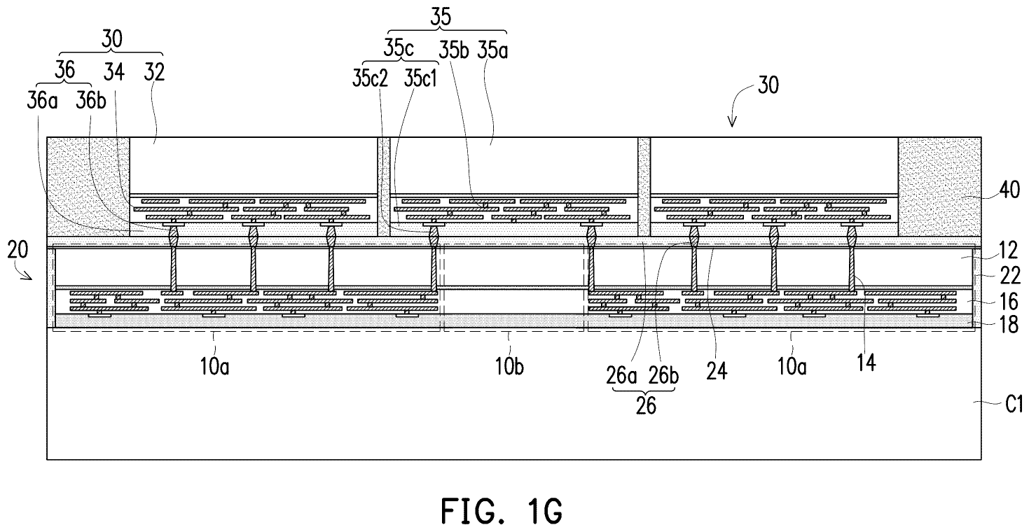

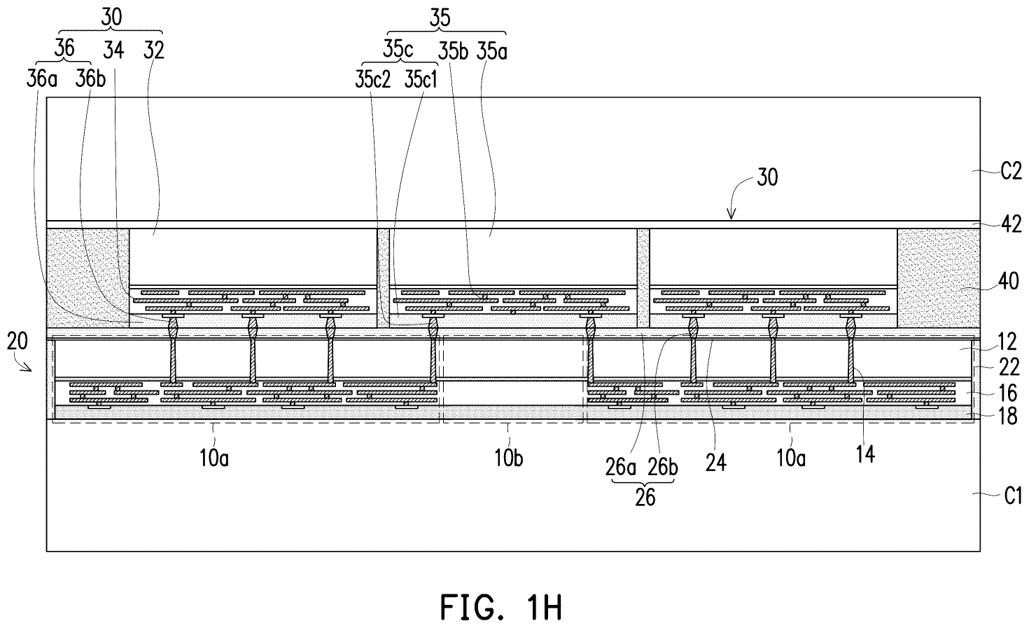

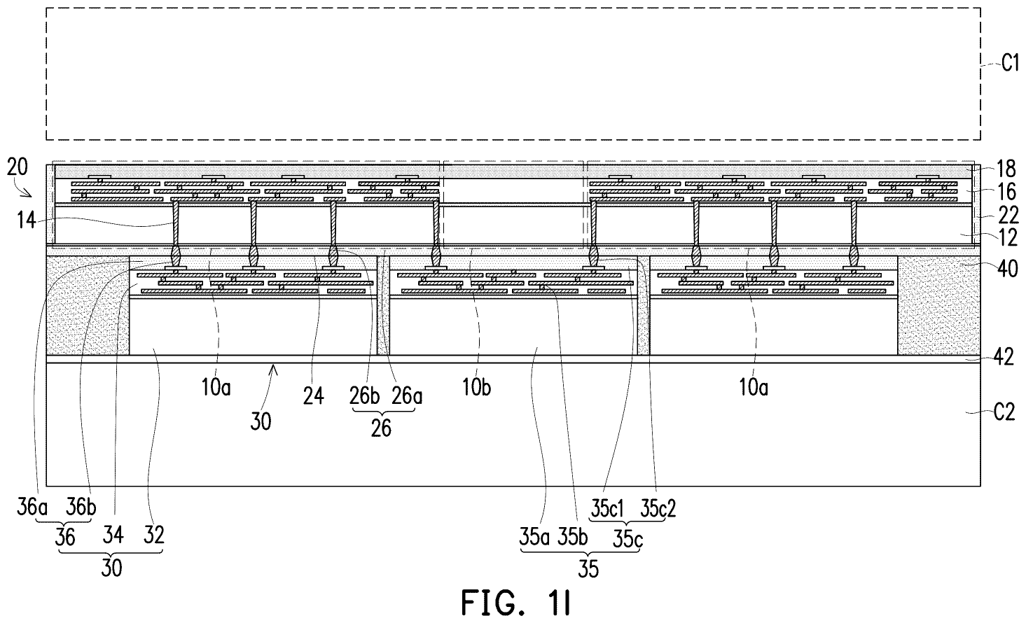

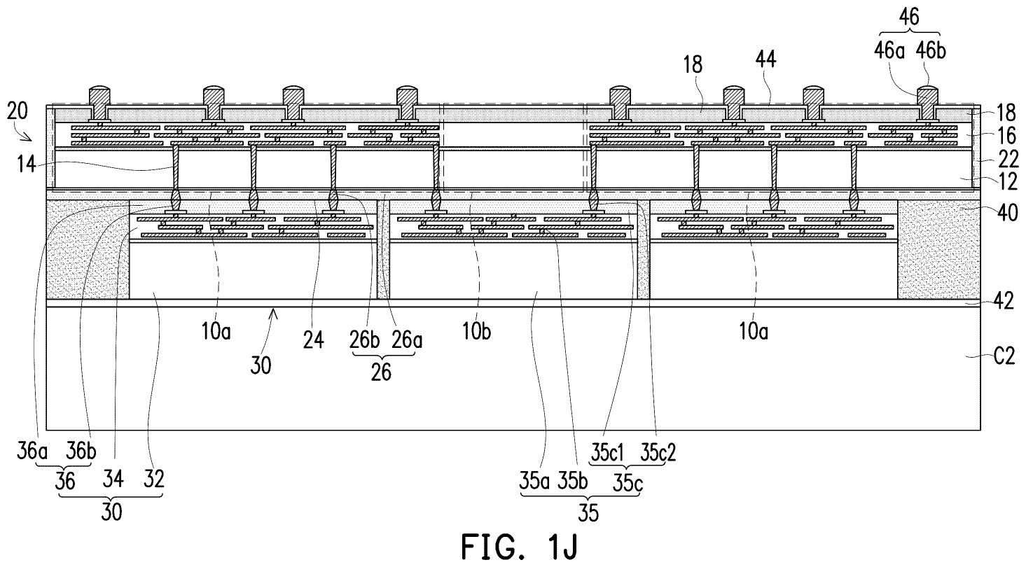

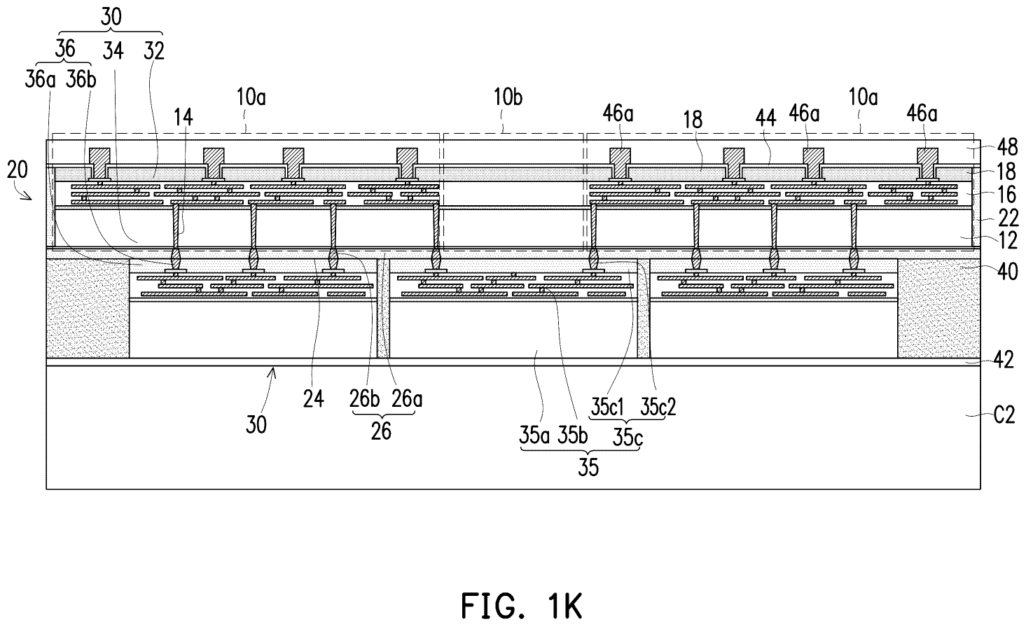

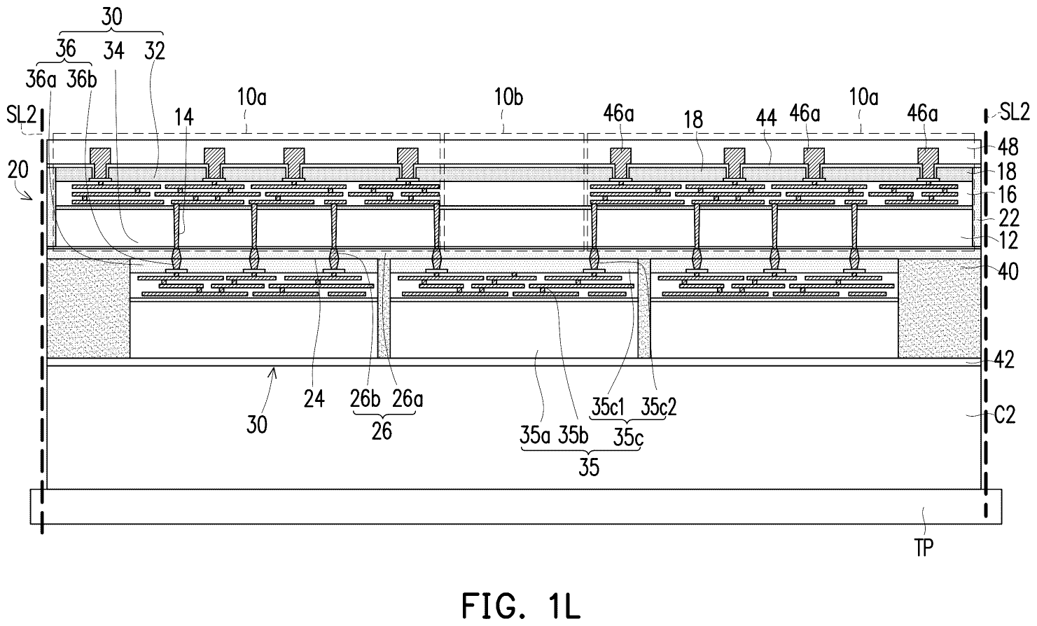

FIGS. 1A through 1L are cross-sectional views schematically illustrating a process flow for fabricating chip stacking structures in accordance with some embodiments of the present disclosure.

Referring to FIG. 1A, a semiconductor wafer 10 including integrated circuit (IC) regions 10a and a dummy region 10b is provided. In the semiconductor wafer 10, the integrated circuit (IC) regions 10a are laterally spaced apart from each other by the dummy region 10b. The integrated circuit (IC) regions 10a may function as logic dies, System-on-Chip (SoC) dies, or other suitable semiconductor dies. The dummy region 10b may have a meshed pattern, and the integrated circuit (IC) regions 10a may be laterally spaced apart from each by the dummy region 10b with meshed pattern. The integrated circuit (IC) regions 10a are electrically insulated from each other by the dummy region 10b at this stage. The semiconductor wafer 10 may include a substrate 12 (e.g., a semiconductor substrate), through substrate vias 14 embedded in the substrates 10, an interconnect structure 16 disposed on the substrate 12, and a protection layer 18 disposed on the interconnect structure 16, wherein the through substrate vias 14 are electrically connected to the interconnect structure 116. The substrate 12 of the semiconductor wafer 10 may include a crystalline silicon wafer. The substrate 12 may include various doped regions depending on design requirements (e.g., p-type substrate or n-type substrate). In some embodiments, the doped regions may be doped with p-type or n-type dopants. The doped regions may be doped with p-type dopants, such as boron or BF₂; n-type dopants, such as phosphorus or arsenic; and/or combinations thereof. The doped regions may be configured for n-type Fin-type Field Effect Transistors (FinFETs) and/or p-type FinFETs. In some alternative embodiments, the substrate 12 may be made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide.

The through substrate vias 14 may be formed by forming recesses in the substrate 12 by, for example, etching, milling, laser techniques, a combination thereof, and/or the like. A thin barrier layer may be conformally deposited over the front side of the substrate 12 and in the openings, such as by chemical vapor deposition (CVD), atomic layer deposition (ALD), physical vapor deposition (PVD), thermal oxidation, a combination thereof, and/or the like. The barrier layer may comprise a nitride or an oxynitride, such as titanium nitride, titanium oxynitride, tantalum nitride, tantalum oxynitride, tungsten nitride, a combination thereof, and/or the like. A conductive material is deposited over the thin barrier layer and in the openings. The conductive material may be formed by an electro-chemical plating process, CVD, ALD. PVD, a combination thereof, and/or the like. Examples of conductive materials are copper, tungsten, aluminum, silver, gold, a combination thereof, and/or the like. Excess conductive material and barrier layer may be removed from the front side of the substrate 12 by, for example, chemical mechanical polishing. Thus, in some embodiments, the through substrate vias 14 may comprise a conductive material and a thin barrier layer between the conductive material and the substrate 12.

The interconnect structure 16 may include one or more dielectric layers (for example, one or more interlayered dielectric (ILD) layers, intermetal dielectric (IMD) layers, or the like) and interconnect wirings embedded in the one or more dielectric layers, and the interconnect wirings are electrically connected to the semiconductor devices (e.g., FinFETs) formed in the substrate 12 and/or the through substrate vias 14. The material of the one or more dielectric layers may include silicon oxide (SiOₓ, where x>0), silicon nitride (SiNₓ, where x>0), silicon oxynitride (SiOₓN_{y}, where x>0 and y>0) or other suitable dielectric material. The interconnect wirings may include metallic wirings. For example, the interconnect wirings include copper wirings, copper pads, aluminum pads or combinations thereof. In some embodiments, the through substrate vias 14 may extend through one or more layers of the interconnect structure 16 and into the substrate 12.

The protection layer 18 may be or include a dielectric layer. The material of the protection layer 18 may be silicon oxide (SiOₓ, where x>0), silicon nitride (SiNₓ, where x>0), silicon oxynitride (SiOₓN_{y}, where x>0 and y>0) or other suitable dielectric material. The protection layer 18 may be formed by depositing a dielectric material through a chemical vapor deposition (CVD) process (e.g., a plasma enhanced CVD process or other suitable process).

As illustrated in FIG. 1A, the through substrate vias 14 are buried in the substrate 12 and the interconnect structure 16. The through semiconductor vias 14 are not revealed from a back surface of the substrate 12 at this stage.

Referring to FIG. 1A and FIG. 1B, the semiconductor wafer 10 is singulated by a wafer sawing process performed along scribe lines SL1 such that singulated semiconductor dies 20 are obtained. Each of the singulated semiconductor dies 20 may include a substrate 12, through substrate vias 14 embedded in the substrate 12, an interconnect structure 16 disposed on the substrate 12, and a protection layer 18 disposed on the interconnect structure 16. Each of the singulated semiconductor dies 20 includes at least two integrated circuit (IC) regions 10a and at least one dummy region 10b, wherein the at least two integrated circuit (IC) regions 10a are laterally spaced apart from each other by the at least one dummy region 10b. In some embodiments, the at least two integrated circuit (IC) regions 10a include a first integrated circuit (IC) region 10a (e.g., the IC region illustrated at the left portion of FIG. 1B) and a second integrated circuit (IC) region 10a (e.g., the IC region illustrated at the right portion of FIG. 1B), and the dummy region 10b is a stripe-shaped dummy region located between the first and second IC regions 10a such that the first and second IC regions 10a arranged side-by-side can be laterally spaced apart from each other by the stripe-shaped dummy region 10b. In some other embodiments, the at least two integrated circuit (IC) regions 10a include four IC regions 10a arranged in a two by two (2x2) array, and the dummy region 10b is a cross-shaped or a mesh-shaped dummy region such that the four IC regions 10a arranged in array can be laterally spaced apart from each other by the cross-shaped or mesh-shaped dummy region 10b.

Referring to FIG. 1C, the singulated semiconductor dies 20 are picked-up and placed on a carrier C1 in side-by-side manner such that front surfaces of the singulated semiconductor dies 20 are bonded to the carrier C1. Although one singulated semiconductor die 20 is illustrated in FIG. 1C, the number of the singulated semiconductor dies 20 placed on the carrier C1 is not limited. The carrier C1 may be a semiconductor wafer such as a silicon wafer. The carrier C1 may have a round top-view shape and a size of a silicon wafer. For example, carrier C1 may have an 8-inch diameter, a 12-inch diameter, or the like. The singulated semiconductor dies 20 are bonded to the carrier C1 through a chip-to-wafer bonding process. A bonding process is performed to bond the protection layer 18 of the singulated semiconductor dies 20 with the carrier C1. The bonding process may be a direct bonding process. After performing the above-mentioned direct bonding process, a semiconductor-to-dielectric bonding interface such as silicon-to-nitride (Si-SiNₓ) bonding interface may be formed between the protection layer 18 and the carrier C1.

In some alternative embodiments, the singulation process of the semiconductor wafer 10 is omitted. In other words, the semiconductor wafer 10 is picked-up and placed on the carrier C1 such that the front surface of the semiconductor wafer 10 is bonded to the carrier C1 through a wafer-to-wafer bonding process.

Referring to FIG. 1D, a gap filling material is formed over the carrier C1 to cover the singulated semiconductor dies 20 which are bonded with the carrier C1. The gap filling material may be a dielectric material (e.g., TEOS formed oxide or other suitable dielectric material), a molding compound (e.g., epoxy or other suitable resin) formed through a gap filling process, an over-molding process, or the like. The gap filling material may cover the back surfaces of the singulated semiconductor dies 20. After forming the gap filling material over the carrier C1, the gap filling material and the semiconductor substrate 12 of the singulated semiconductor dies 20 is partially removed such that the semiconductor substrates 12 of the semiconductor dies 20 are thinned and a gap filling layer 22 are formed to laterally encapsulate the singulated semiconductor dies 20. The gap filling material and the semiconductor substrate 12 of the singulated semiconductor dies 20 may be partially remove through a planarization process such as a Chemical Mechanical Polish (CMP) process, a mechanical grinding process or the combinations thereof. After performing the above-mentioned planarization process, the thickness of the gap filling layer 22 is substantially equal to that of the singulated semiconductor dies 20. In other words, the top surface of the gap filling layer 22 is substantially level with the back surface of the singulated semiconductor dies 20.

As illustrated in FIG. 1D, after performing the above-mentioned planarization process, the through semiconductor vias 14 are revealed from the back surface of the semiconductor substrate 12 at this stage. The through semiconductor vias 14 may protrude from the back surface of the semiconductor substrate 12.

In some alternative embodiments where the singulation process of the semiconductor wafer 10 is omitted, the formation of the gap filling layer 22 are omitted because the semiconductor wafer 10 is bonded to the carrier C1 through a wafer-to-wafer bonding process.

Referring to FIG. 1E, a dielectric material may be formed over the back surfaces of the semiconductor substrates 12 and the top surface of the gap filling layer 22 to cover the revealed through semiconductor vias 14. The dielectric material may be or include silicon oxide (SiOₓ, where x>0), silicon nitride (SiNₓ, where x>0), silicon oxynitride (SiOₓN_{y}, where x>0 and y>0) or other suitable dielectric material. A planarization process such as a Chemical Mechanical Polish (CMP) process, a mechanical grinding process or the combinations thereof may be performed to partially remove the dielectric material such that a planarization layer 24 is formed on the back surface of the semiconductor substrate 12 and the top surface of the gap filling layer 22. The top surface of the planarization layer 24 is substantially level with top ends of the through semiconductor vias 14.

After forming the planarization layer 24, a bonding structure 26 including a bonding dielectric layer 26a and bonding conductors 26b embedded in the bonding dielectric layer 26a. The material of the bonding dielectric layer 26a may be silicon oxide (SiOₓ, where x>0), silicon nitride (SiNₓ, where x>0), silicon oxynitride (SiOₓN_{y}, where x>0 and y>0) or other suitable dielectric material, and the bonding conductors 26b may be conductive vias (e.g., copper vias), conductive pads (e.g., copper pads) or combinations thereof. The bonding structure 26 may be formed by depositing a dielectric material through a chemical vapor deposition (CVD) process (e.g., a plasma enhanced CVD process or other suitable process); patterning the dielectric material to form the bonding dielectric layer 26a including openings or through holes; and filling conductive material in the openings or through holes defined in the bonding dielectric layer 26a to form the bonding conductors 26b embedded in the bonding dielectric layer 26a. In some embodiments, the conductive material for forming the bonding conductors 26b may be formed through a chemical vapor deposition (CVD) process (e.g., a plasma enhanced CVD process or other suitable process) followed by a planarization process (e.g., a Chemical Mechanical Polish (CMP) process and/or a mechanical grinding process).

After forming the bonding structure 26, at least two semiconductor dies 30 and at least one bridge die 35 are provided on the bonding structure 26. The at least two semiconductor dies 30 are disposed over and cover the IC regions 10a of each of the semiconductor dies 20, and the at least one bridge die 35 is disposed over and covers the dummy region 10b of each of the semiconductor dies 20. The semiconductor dies 30 may be logic dies, System-on-Chip (SoC) dies or other suitable semiconductor dies. The semiconductor dies 30 may be fabricated through, for example, N3 process. The semiconductor dies 20 and the semiconductor dies 30 may perform the same function or different functions. For example, the semiconductor dies 20 and the semiconductor dies 30 are System on Chip (SoC) dies. Each of the semiconductor dies 30 may respectively include a semiconductor substrate 32 and an interconnect structure 34 disposed on the semiconductor substrate 32. Furthermore, bonding structures 36 may be formed on the interconnect structures 34 of the semiconductor dies 30. The bonding structure 36 includes a bonding dielectric layer 36a and bonding conductors 36b embedded in the bonding dielectric layer 36a. The material of the bonding dielectric layer 36a may be silicon oxide (SiOₓ, where x>0), silicon nitride (SiNₓ, where x>0), silicon oxynitride (SiOₓN_{y}, where x>0 and y>0) or other suitable dielectric material, and the bonding conductors 36b may be conductive vias (e.g., copper vias), conductive pads (e.g., copper pads) or combinations thereof. The bonding structure 36 may be formed by depositing a dielectric material through a chemical vapor deposition (CVD) process (e.g., a plasma enhanced CVD process or other suitable process); patterning the dielectric material to form the bonding dielectric layer 36a including openings or through holes; and filling conductive material in the openings or through holes defined in the bonding dielectric layer 36a to form the bonding conductors 36b embedded in the bonding dielectric layer 36a. In some embodiments, the conductive material for forming the bonding conductors 36b may be formed through a chemical vapor deposition (CVD) process (e.g., a plasma enhanced CVD process or other suitable process) followed by a planarization process (e.g., a Chemical Mechanical Polish (CMP) process and/or a mechanical grinding process).

The bridge die 35 may include a semiconductor substrate 35a and an interconnect structure 35b disposed on the semiconductor substrate 35a. Furthermore, a bonding structure 35c is formed on the interconnect structure 35b. The bonding structure 35c includes a bonding dielectric layer 35cl and bonding conductors 35c2 embedded in the bonding dielectric layer 35c1. The material of the bonding dielectric layer 35cl may be silicon oxide (SiOₓ, where x>0), silicon nitride (SiNₓ, where x>0), silicon oxynitride (SiOₓN_{y}, where x>0 and y>0) or other suitable dielectric material, and the bonding conductors 35c2 may be conductive vias (e.g., copper vias), conductive pads (e.g., copper pads) or combinations thereof. The bonding structure 35c may be formed by depositing a dielectric material through a chemical vapor deposition (CVD) process (e.g., a plasma enhanced CVD process or other suitable process); patterning the dielectric material to form the bonding dielectric layer 35cl including openings or through holes; and filling conductive material in the openings or through holes defined in the bonding dielectric layer 35cl to form the bonding conductors 35c2 embedded in the bonding dielectric layer 35cl. In some embodiments, the conductive material for forming the bonding conductors 35c2 may be formed through a chemical vapor deposition (CVD) process (e.g., a plasma enhanced CVD process or other suitable process) followed by a planarization process (e.g., a Chemical Mechanical Polish (CMP) process and/or a mechanical grinding process). The bridge die 35 may include bridge wirings distributed in the interconnect structure 35b and/or bonding structure 35c. In some embodiments, the bridge die 35 provides signal bridge function only, and no further signal processing is performed by the bridge die 35. In some other embodiments, the bridge die 35 may not only provide signal bridge function, but also provide less signal processing capability compared to each of the semiconductor dies 30. In other words, the semiconductor dies 30 may provide better signal processing capability than the bridge die 35. In some alternative embodiments, the semiconductor dies 30 are fabricated by advanced wafer process with small technology node (e.g., 7 nm process, 3 nm process, 2 nm process, 1 nm process, and so on), and the bridge die 35 are fabricated by wafer process with large technology node (e.g., 14 nm process, 28 nm process, and so on).

In some embodiments, no transistor (e.g., planar FETs, FinFETs, and/or Gate-All-Around FETs) and isolation structure (e.g., shallow trench isolation (STI) structures, Field Oxide (FOX) structures, and so on) fabricated by front end of line (FEOL) processes are formed in the semiconductor substrate 35a of the bridge die 35. In other words, the fabrication of the bride die 35 may be merely involved with the back-end of line (BEOL) processes.

In some embodiments, the number of the semiconductor dies 30 equals to the number of the IC regions 10a of each of the semiconductor dies 20, and the number of the bridge die 35 may be modified in accordance with the number of the IC regions 10a of the semiconductor dies 20. In the embodiment where each of the semiconductor dies 20 includes two IC regions 10a, the two IC regions 10a may communicate with each other through one or more bridge dies 35. In the embodiment where each of the semiconductor dies 20 includes four IC regions 10a arranged in 2×2 array, the four IC regions 10a may communicate with each other through four or more bridge dies 35.

A bonding process (e.g., a chip-to-wafer bonding process) is performed to bond the bonding structures 36 formed on the semiconductor dies 30 as well as the bonding structure 35c of the bridge die 35 with bonding regions of the bonding structure 26. The bonding process may be a hybrid bonding process that includes dielectric-to-dielectric bonding and metal-to-metal bonding. After performing the above-mentioned bonding process, a dielectric-to-dielectric bonding interfaces are formed between the bonding dielectric layer 26a and the bonding dielectric layer 36a as well as between the bonding dielectric layer 35cl and the bonding dielectric layer 36a, and metal-to-metal bonding interfaces are formed between the bonding conductors 26b and bonding conductors 36b as well as between the bonding conductors 26b and bonding conductors 35c2. After performing the bonding process, the semiconductor dies 30 and IC regions 10a of the semiconductor dies 20 are electrically connected to each other through the bridge die 35 and the bonding structure 26.

As illustrated in FIG. 1E, the lateral dimension (e.g., width and/or length) of the semiconductor dies 30 and the bridge die 35 may be less than the lateral dimension (e.g., width and/or length) of the semiconductor dies 20. In other words, the footprint of the semiconductor dies 20 may be greater than those of the semiconductor dies 30 and the bridge die 35. Since the bonding structures 36 of the semiconductor dies 30 and the bonding structures 35c of the bridge die 35 are merely bonded with bonding regions of the bonding structure 26, portions of the bonding dielectric layer 26a are not covered by the bonding structure 36 and bonding structures 35c.

Referring to FIG. 1F and FIG. 1G, a gap filling material 38 is formed to cover the back surfaces of the semiconductor dies 30, sidewalls of the semiconductor dies 30, the back surface of the bridge die 35, sidewalls of the bridge die 35, sidewalls of the bonding structures 36, sidewalls of the bonding structure 35c, and the portions of the bonding dielectric layer 26a which are not covered by the bonding structures 36 and 35c. The gap filling material 38 may be a dielectric material (e.g., TEOS formed oxide or other suitable dielectric material), a molding compound (e.g., epoxy or other suitable resin) formed through a gap filling process, an over-molding process, or the like. The gap filling material 38 fills the gaps between neighboring semiconductor dies 30 and bridge die 3. After forming the gap filling material 38, the gap filling material 38 is partially removed until the substrates 32 of the semiconductor dies 30 and the substrate 35a of the bridge die 35 are revealed such that a gap filling layer 40 is formed. The gap filling material 38 may be partially removed through a planarization process such as a Chemical Mechanical Polish (CMP) process and/or a mechanical grinding process. After performing the above-mentioned planarization process, the top surface of the gap filling 40 is substantially level with back surfaces of the semiconductor dies 30 and the bridge die 35.

Referring to FIG. 1H, a support substrate C2 including an adhesive layer 42 formed thereon is provided. In some embodiments, the support substrate C2 is a silicon substrate, a glass substrate, a ceramic carrier, or the like. The support substrate C2 may have a round top-view shape. For example, the support substrate C2 may have an 8-inch diameter, a 12-inch diameter, or the like. The adhesive layer 42 may be formed of a polymer-based adhesive material, which may adhere between the resulted structure formed on the carrier C1 and the support substrate C2. In some embodiments, the adhesive layer 42 may be dispensed as a liquid and cured. In alternative embodiments, the adhesive layer 42 is a laminate film and is laminated onto the support substrate C2. The top surface of the adhesive layer 42 is substantially planar.

A bonding process (e.g., a wafer-to-wafer bonding process) is performed to bond the resulted structure formed on the carrier C1 with the adhesive layer 42 carried by the support substrate C2. After the resulted structure formed on the carrier C1 is bonded with the adhesive layer 42 carried by the support substrate C2, the top surface of the gap filling layer 40, the back surfaces of the semiconductor dies 30 and the back surface of the bridge die 35 are in contact with the adhesive layer 42.

Referring to FIG. 1H and FIG. 1I, after the resulted structure formed on the carrier C1 is bonded with the adhesive layer 42 carried by the support substrate C2, the carrier C1 is de-bonded from the protection layer 18 and the gap filling layer 22 such that the protection layer 18 and the gap filling layer 22 are revealed.

Referring to FIG. 1I and FIG. 1J, the protection layer 18 is patterned to form openings such that the topmost interconnect wirings of the interconnect structures 16 are revealed by the openings formed in the protection layer 18. The formation of the openings in the protection layer 18 may be performed through a photolithography process. A passivation layer 44 including openings formed therein may be formed to cover the protection layer 18 such that the topmost interconnect wirings of the interconnect structures 16 revealed by the openings of the passivation layer 44. The formation of the openings in the passivation layer 44 may be performed through a photolithography process. The width of the openings defined in the passivation layer 44 may be smaller than the width of the openings defined in the protection layer 18. The passivation layer 44 may cover the top surfaces of the protection layer 18 and the gap filling layer 22. The passivation layer 44 may further extend into the openings defined in the protection layer 18 such that the passivation layer 44 is in contact with the topmost interconnect wirings of the interconnect structures 16.

After forming the passivation layer 44, conductive terminals 46 are formed over the passivation layer 44. The conductive terminals 46 are electrically connected to the interconnect wirings of the interconnect structures 16 and protrude from the passivation layer 44. Each of the conductive terminals 46 may respectively include a conductive pillar 46a and a solder cap 46b disposed on the conductive pillar 46a. The conductive pillars 46a fill the openings defined in the passivation layer 44 and protrude from the passivation layer 44. The solder caps 46b covers the top surfaces of the conductive pillars 46a. After forming the conductive terminals 46, a chip probing process may be performed to increase yields. The formation of the conductive terminals 46 may include forming a seed layer (not shown) over the passivation layer 44, forming a patterned mask (not shown) such as a photoresist layer over the seed layer, and then performing a plating process on the exposed seed layer. The patterned mask and the portions of the seed layer covered by the patterned mask are then removed, leaving the conductive terminals 46. A reflow process may be further performed to re-shape the profile of the solder caps 46a. In accordance with some embodiments, the seed layer includes a titanium layer and a copper layer over the titanium layer. The seed layer may be formed using, for example, Physical Vapor Deposition (PVD). The plating may be performed using, for example, electroless plating.

Referring to FIG. 1J and FIG. 1K, after performing the chip probing process, the solder caps 46b are removed and a dielectric layer 48 is formed over the passivation layer 44 to cover the conductive pillars 46a. In some embodiments, the dielectric layer 48 is formed of a polymer, which may be a photo-sensitive material such as polybenzoxazole (PBO), polyimide, benzocyclobutene (BCB), or the like. In some other embodiments, the dielectric layer 48 is formed of a nitride such as silicon nitride, an oxide such as silicon oxide, PhosphoSilicate Glass (PSG), BoroSilicate c Glass (BSG), Boron-doped PhosphoSilicate Glass (BPSG), or the like.

Referring to FIG. 1K and FIG. 1L, a tape TP carried by a frame is provided, and the resulted structure illustrated in FIG. 1K is attached onto tape TP. Then, a singulation process is performed along scribe lines SL2 such that singulated chip stacking structures 100 (i.e., SoIC structures) are obtained. During the singulation process, the dielectric layer 48, the passivation layer 44, the gap filling layer 22, the planarization layer 24, the bonding structure 26, the gap filling layer 40, the adhesive layer 42 and the support substrate C2 are cut along scribe lines SL2. In some embodiments, the gap filling layer 22 laterally encapsulates the semiconductor dies 20, and sidewalls of the gap filling layer 40 insulating encapsulant are substantially aligned with sidewalls of the gap filling layer 22.

As illustrated in FIG. 1L, the singulated chip stacking structure 100 (i.e., the SoIC structure) includes the semiconductor die 20, semiconductor dies 30, the bridge die 35, and the gap filling material 40. The semiconductor die 20 includes integrated circuit regions 10a (e.g., a first IC region and a second IC regions laterally spaced apart from the first IC region) laterally spaced apart from each other. The semiconductor dies 30 are disposed over and electrically connected to the semiconductor die 20. The bridge die 35 is disposed over and electrically connected to the semiconductor die 20, and the integrated circuit regions 10 are electrically connected to each other through the bridge die 35. The gap filling material 40 is disposed on the semiconductor die 20 to laterally encapsulate the bridge die 35 and the semiconductor dies 30.

In some embodiments, the semiconductor die 20 includes the bonding structure 26, each of the semiconductor dies 30 includes the bonding structure 36, the bridge die 35 includes the bonding structure 35c, the bonding structure 36 of each of the semiconductor dies 30 is in contact with and electrically connected to the bonding structure 26, and the bonding structure 35c is in contact with and electrically connected to the bonding structure 26. In some embodiments, the semiconductor die 20 includes the semiconductor substrate 12, the interconnect structure 16 disposed on the semiconductor substrate 12, and bonding structure 26 is disposed on and electrically connected to the interconnect structure 16; each of the semiconductor dies 30 includes the semiconductor substrate 32, the interconnect structure 34 disposed on the semiconductor substrate 32, and the bonding structure 36 disposed on and electrically connected to the interconnect structure 34; the bridge die 35 includes the semiconductor substrate 35a, the interconnect structure 35b disposed on the semiconductor substrate 35a, and the bonding structure 35c disposed on and electrically connected to the interconnect structure 35b; the bonding structure 36 of each of the semiconductor dies 30 is in contact with and electrically connected to the bonding structure 26; and the bonding structure 35c is in contact with and electrically connected to the bonding structure 26. In some embodiments, the semiconductor die 20 further includes conductive through vias 14 penetrating through the semiconductor substrate 12, the interconnect structure 16 and the bonding structure 26 are disposed on opposite sides of the semiconductor substrate 12, and the interconnect structure 16 is electrically connected to the bonding structure 26 through the conductive through vias 14. In some embodiments, the integrated circuit regions 10 are electrically connected to each other through the bridge die 35 and bonding structure 26.

In some embodiments, the singulated chip stacking structure 100 (i.e., the SoIC structure) further includes conductive terminals 46a disposed on and electrically connected to the interconnect structure 16 of the semiconductor die 20. In some embodiments, as shown in FIG. 1E, the bonding structure 26 includes the bonding dielectric layer 26a and bonding conductors 26b embedded in the bonding dielectric layer 26a; the bonding structure 36 includes the bonding dielectric layer 36a and bonding conductors 36b embedded in the bonding dielectric layer 36a; the bonding structure 35c includes the bonding dielectric layer 35cl and bonding conductors 35c2 embedded in the bonding dielectric layer 35c1, wherein the bonding conductors 26b are bonded to the bonding conductors 36b and the bonding conductors 35c2, and the bonding dielectric layer 36a and bonding dielectric layer 35cl are bonded to portions of the bonding dielectric layer 26a. In some embodiments, the semiconductor dies 30 are arranged side-by-side on the semiconductor die 20, and the bridge die 35 is disposed between the semiconductor dies 30. In some embodiments, the singulated chip stacking structure 100 (i.e., the SoIC structure) further includes a support substrate C2, wherein the gap filling material 40, the semiconductor dies 30 and the bridge die 35 are disposed between the support substrate C2 and the semiconductor die 20. In some embodiments, the semiconductor die 20 further includes a dummy region 10b, and the integrated circuit regions 10a are spaced apart from each other by the dummy region 10b. In some embodiments, the bridge die 35 is disposed over and covers the dummy region 10b.

In some embodiments, the singulated chip stacking structure 100 (i.e., the SoIC structure) further includes an adhesive layer 42, wherein the support substrate C2 is adhered to the gap filling material 40, the semiconductor dies 30 and the bridge die 35 by the adhesive layer 42. In some embodiments, sidewalls of the support substrate C2 substantially align with sidewalls of the gap filling material 40 and sidewalls of the semiconductor die 20. In some embodiments, the support substrate C2 and the semiconductor die 20 are substantially identical in lateral dimension. In some embodiments, the semiconductor dies 30 and the bridge die 35 are substantially identical in thickness.

As illustrated in FIG. 1L, no gap filling material is formed between the IC regions 10a of the semiconductor die 20, and the dummy region of the semiconductor die 20 which is covered by the bridge die 35 is a semiconductor dummy region (e.g., silicon dummy region). In such configuration of the chip stacking structure 100 (i.e., the SoIC structure), the fabrication processes and the chip integration can be simplified. Accordingly, fabrication costs of the chip stacking structure 100 (i.e., the SoIC structure) can be reduced.

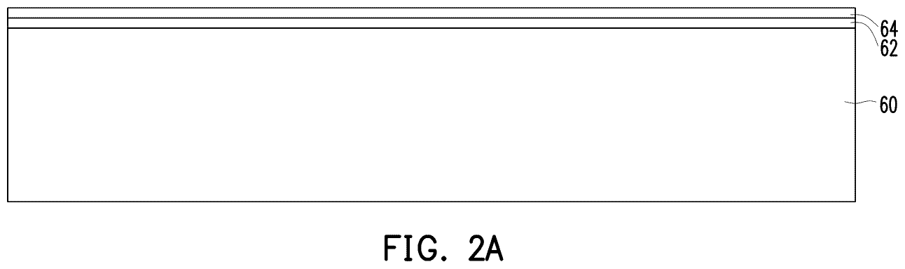

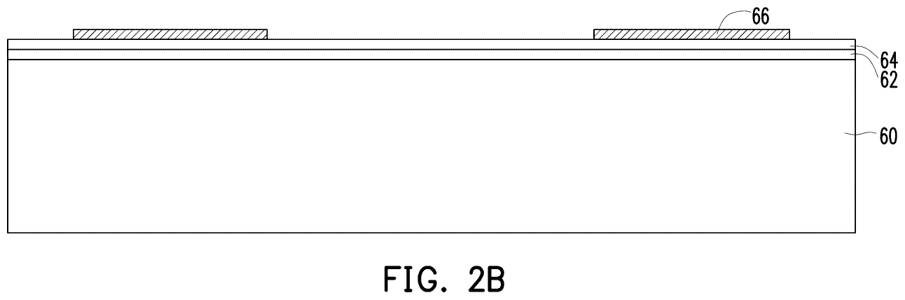

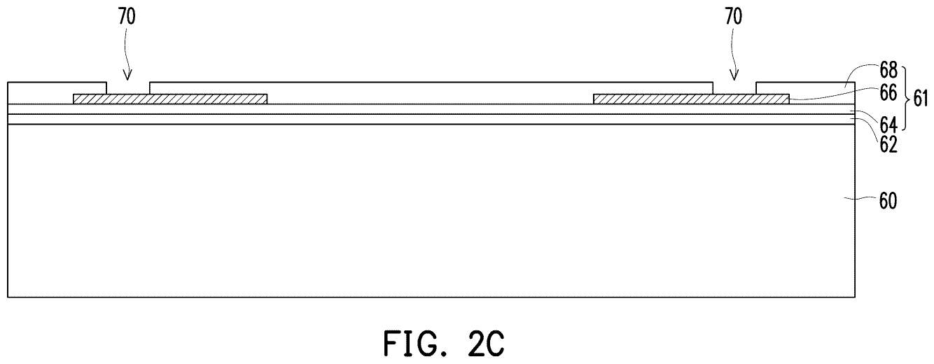

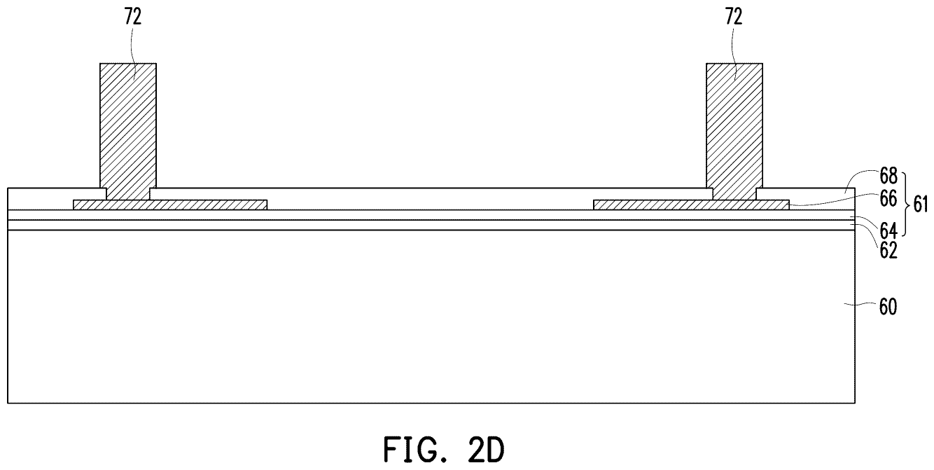

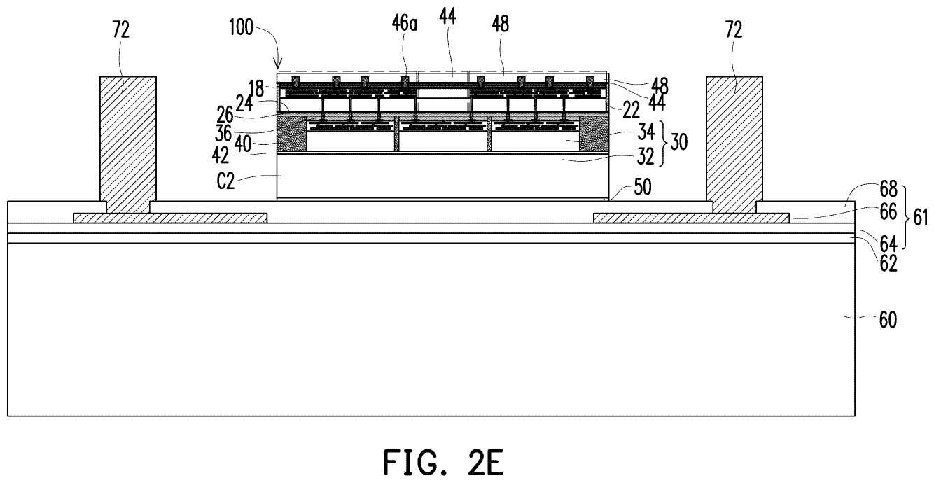

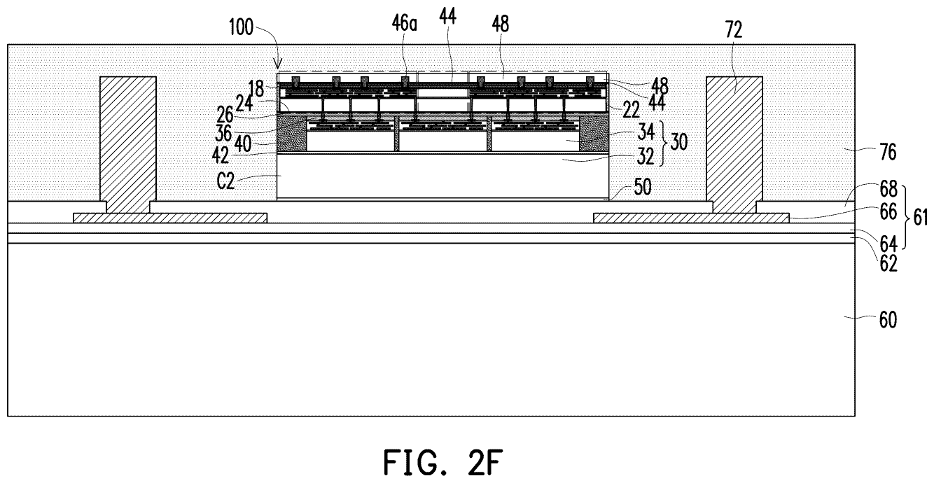

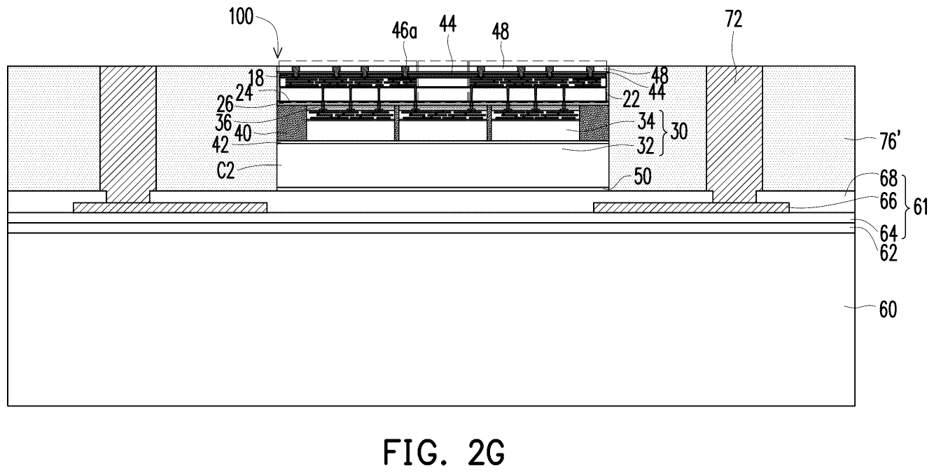

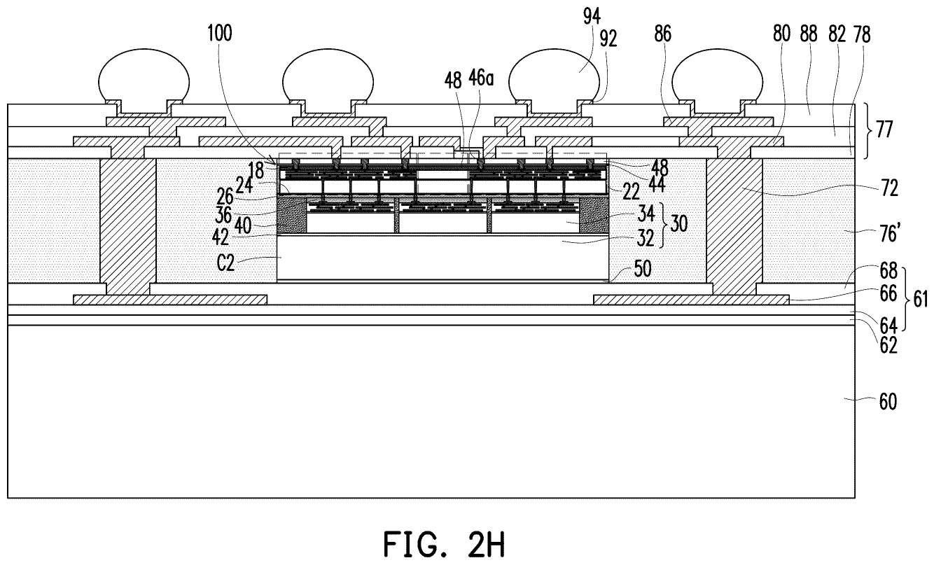

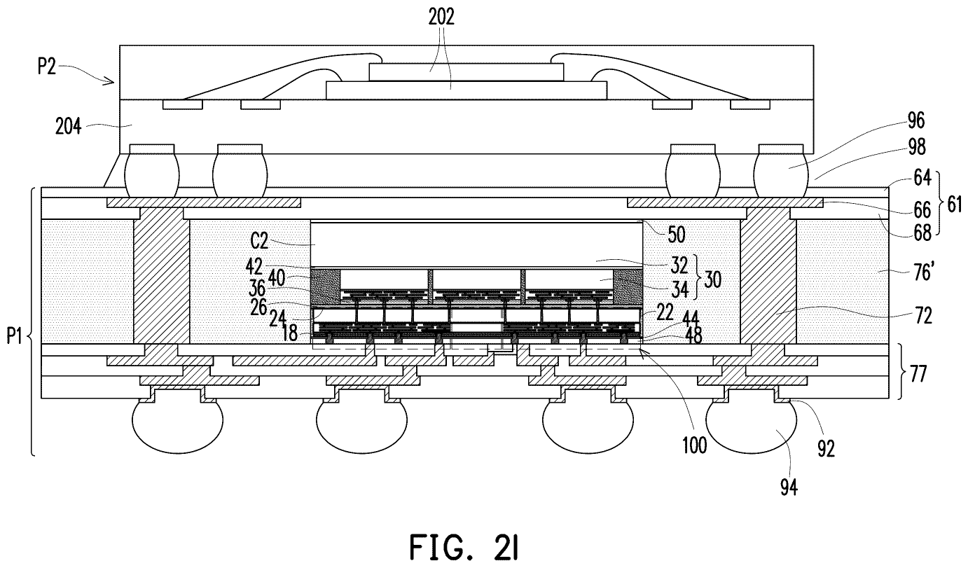

The singulated chip stacking structure 100 (i.e., the SoIC structure) may be packed by integrated fan-out (InFO) package process, as illustrated in FIGS. 2A through 2I. However, the singulated chip stacking structure 100 (i.e., the SoIC structure) may be also packed by other suitable package processes, such as Chip-on-Wafer-on-Substrate (CoWoS) package process, System on Integrated Substrate (SoIS) package process, and so on.

FIGS. 2A through 2I are cross-sectional views schematically illustrating a process flow for fabricating a POP structure in accordance with some embodiments of the present disclosure.

Referring to FIG. 2A, a carrier 60 including a de-bonding layer 62 formed thereon is provided. In some embodiments, the carrier 60 is a glass substrate, a ceramic carrier, or the like. The carrier 60 may have a round top-view shape and a size of a silicon wafer. For example, carrier 60 may have an 8-inch diameter, a 12-inch diameter, or the like. The de-bonding layer 62 may be formed of a polymer-based material (e.g., a Light-To-Heat-Conversion (LTHC) material), which may be subsequently removed along with the carrier 60 from the overlying structures that will be formed in subsequent steps. In some embodiments, the de-bonding layer 62 is formed of an epoxy-based thermal-release material. In other embodiments, the de-bonding layer 62 is formed of an ultra-violet (UV) glue. The de-bonding layer 62 may be dispensed as a liquid and cured. In alternative embodiments, the de-bonding layer 62 is a laminate film and is laminated onto the carrier 60. The top surface of the de-bonding layer 62 is substantially planar.

Referring to FIGS. 2A through 2C, a redistribution circuit structure 61 including a dielectric layer 64, redistribution wirings 66 and a dielectric layer 68 is formed on the de-bonding layer 62 such that the de-bonding layer 62 is between the carrier 60 and the dielectric layer 64 of the redistribution circuit structure 61. As shown in FIG. 2A, the dielectric layer 64 is formed on the de-bonding layer 62. In some embodiments, the dielectric layer 64 is formed of a polymer, which may also be a photo-sensitive material such as polybenzoxazole (PBO), polyimide, benzocyclobutene (BCB), or the like, which may be easily patterned using a photolithography process. In some embodiments, the dielectric layer 64 is formed of a nitride such as silicon nitride, an oxide such as silicon oxide, PhosphoSilicate Glass (PSG), BoroSilicate Glass (BSG), Boron-doped PhosphoSilicate Glass (BPSG), or the like. As shown in FIG. 2B, the redistribution wirings 66 are formed over the dielectric layer 64. The formation of the redistribution wirings 66 may include forming a seed layer (not shown) over the dielectric layer 64, forming a patterned mask (not shown) such as a photoresist layer over the seed layer, and then performing a plating process on the exposed seed layer. The patterned mask and the portions of the seed layer covered by the patterned mask are then removed, leaving the redistribution wirings 66 as shown in FIG. 2B. In accordance with some embodiments, the seed layer includes a titanium layer and a copper layer over the titanium layer. The seed layer may be formed using, for example, Physical Vapor Deposition (PVD). The plating may be performed using, for example, electroless plating. As shown in FIG. 2C, the dielectric layer 68 is formed over the dielectric layer 64 to cover the redistribution wirings 66. The bottom surface of the dielectric layer 68 is in contact with the top surfaces of the redistribution wirings 66 and the dielectric layer 64. In accordance with some embodiments of the present disclosure, the dielectric layer 68 is formed of a polymer, which may be a photo-sensitive material such as PBO, polyimide, BCB, or the like. In some embodiments, the dielectric layer 68 is formed of a nitride such as silicon nitride, an oxide such as silicon oxide, PSG, BSG, BPSG, or the like. The dielectric layer 68 is then patterned to form openings 70 therein. Hence, portions of the redistribution wirings 66 are exposed through the openings 70 in the dielectric layer 68. FIG. 2C and the subsequent figures illustrate a single redistribution circuit structure 61 having a single layer of redistribution wirings 66 for illustrative purposes and some embodiments may have a plurality of layers of redistribution wirings 66 by repeating the process discussed above.

Referring to FIG. 2D, after forming the redistribution circuit structure 61 over the de-bonding layer 62 carried by the carrier 60, metal posts 72 are formed on the redistribution circuit structure 61 and electrically connected to the redistribution wirings 66 of the redistribution circuit structure 61. Throughout the description, the metal posts 72 are alternatively referred to as conductive through vias 72 since the metal posts 72 penetrate through the subsequently formed molding material (shown in FIG. 2G). In some embodiments, the conductive through vias 72 are formed by plating. The plating of the conductive through vias 72 may include forming a blanket seed layer (not shown) over the dielectric layer 68 and extending into the openings 70 shown in FIG. 2C, forming and patterning a photoresist (not shown), and plating the conductive through vias 72 on the portions of the seed layer that are exposed through the openings in the photoresist. The photoresist and the portions of the seed layer that were covered by the photoresist are then removed. The material of the conductive through vias 72 may include copper, aluminum, or the like. The conductive through vias 72 may have the shape of rods. The top-view shapes of the conductive through vias 72 may be circles, rectangles, squares, hexagons, or the like.

Referring FIG. 2E, after forming the conductive through vias 72, a die attachment film 50 is provided on the bottom surface of the support substrate C2. In some embodiments, the die attachment film 50 is formed on the bottom surface of the support substrate C2 before the singulation process illustrated in FIG. 1L. In some other embodiments, the attachment film 54 shown in FIG. 2E is optional.

At least one singulated chip stacking structure 100 is picked-up and placed onto the redistribution circuit structure 61. The at least one singulated chip stacking structure 100 may be attached to the redistribution circuit structure 61 through the die attachment film 50. Only a single chip stacking structure 100 and its surrounding conductive through vias 72 are illustrated in FIG. 2E for illustrative purposes. It is noted, however, that the process steps shown in FIGS. 2A through 2I may be performed at wafer level. The chip stacking structure 100 is surrounded by the conductive through vias 72. As illustrated in FIG. 2E, the die attachment film 50 is adhered between the chip stacking structure 100 and the is adhered to the redistribution circuit structure 61.

Referring to FIG. 2F, an insulating encapsulation material 76 is formed over the redistribution circuit structure 61 to cover the chip stacking structure 100 and the conductive through vias 72. The insulating encapsulation material 76 may be a molding compound (e.g., epoxy or other suitable resin) formed through an over-molding process. The insulating encapsulation material 76 fills the gaps between neighboring conductive through vias 72, but also fills the gaps between the conductive through vias 72 and the chip stacking structure 100. The insulating encapsulation material 76 covers the top surface of the dielectric layer 48 of the chip stacking structure 100.

Next, as shown in FIG. 2F and FIG. 2G, a planarization such as a Chemical Mechanical Polish (CMP) process and/or a mechanical grinding process is performed to partially remove the insulating encapsulation material 76 and the dielectric layer 48 of the chip stacking structure 100 until the conductive through vias 72 and the conductive pillars 46a of the chip stacking structure 100 are revealed. After the insulating encapsulation material 76 is thinned, as illustrated in FIG. 2G, an insulating encapsulant 76′ is formed to laterally encapsulate the chip stacking structure 100 and the conductive through vias 72. Due to the planarization, the conductive through vias 72 penetrate though the insulating encapsulant 76′, the top ends of the conductive through vias 72 are substantially level or coplanar with the top surface of the dielectric layer 48, and are substantially level or coplanar with the top surface of the insulating encapsulant 76′, within process variations. In the illustrated exemplary embodiments, the planarization is performed until the conductive through vias 72 and the conductive pillars 46a of the chip stacking structure 100 are revealed.

Referring to FIGS. 2H, a redistribution circuit structure 77 including a dielectric layer 78, redistribution wirings 80, a dielectric layer 82, redistribution wirings 86, and a dielectric layer 88 is formed on the chip stacking structure 100 and the insulating encapsulant 76′. After forming the redistribution circuit structure 77, solder regions including Under-Bump Metallurgies (UBMs) 92 and electrical connectors 94 disposed on the UBMs 92 are formed on the redistribution circuit structure 77.

The dielectric layer 78 is formed to cover the dielectric 48, the conductive pillars 46a and the insulating encapsulant 76′. In some embodiments, the dielectric layer 78 is formed of a polymer such as PBO, polyimide, or the like. In some other embodiments, dielectric layer 78 is formed of silicon nitride, silicon oxide, or the like. Openings may be formed in the dielectric layer 78 to expose conductive through vias 72 and the conductive pillars 46a. The formation of the openings in the dielectric layer 78 may be performed through a photolithography process.

Next, the redistribution wirings 80 are formed to connect to the conductive pillars 46a and the conductive through vias 72. The redistribution wirings 80 may also interconnect the conductive pillars 46a and the conductive through vias 72. The redistribution wirings 80 may include metal traces (metal lines) over the dielectric layer 78 as well as metal vias extending into the openings defined in the dielectric layer 78 so as to electrically connect to the conductive through vias 72 and the conductive pillars 46a. In some embodiments, the redistribution wirings 80 are formed by a plating process, wherein each of the redistribution wirings 80 includes a seed layer (not shown) and a plated metallic material over the seed layer. The seed layer and the plated material may be formed of the same material or different materials. The redistribution wirings 80 may include a metal or a metal alloy including aluminum, copper, tungsten, and alloys thereof. The redistribution wirings 80 may be formed of non-solder materials. The via portions of the redistribution wirings 80 may be in physical contact with the top surfaces of the conductive through vias 72 and the conductive pillars 46a.

The dielectric layer 82 is then formed over the redistribution wirings 80 and the dielectric layer 78. The dielectric layer 82 may be formed using a polymer, which may be selected from the same candidate materials as those of the dielectric layer 78. For example, the dielectric layer 82 may include PBO, polyimide, BCB, or the like. In some embodiments, the dielectric layer 82 may include non-organic dielectric materials such as silicon oxide, silicon nitride, silicon carbide, silicon oxynitride, or the like. Openings may be also formed in the dielectric layer 82 to expose the redistribution wirings 80. The formation of the openings defined in the dielectric layer 82 may be performed through a photolithography process. The formation of the redistribution wirings 86 may adopt similar methods and materials to those for forming the redistribution wirings 80.

The dielectric layer 88, which may be a polymer layer, may be formed to cover the redistribution wirings 86 and the dielectric layer 82. The dielectric layer 88 may be selected from the same candidate polymers used for forming the dielectric layers 78 and 82. Openings may be formed in the dielectric layer 88 to expose the metal pad portions of redistribution wirings 86. The formation of the openings defined in the dielectric layer 88 may be performed through a photolithography process.

The formation of the UBMs 92 may include deposition and patterning. The formation of the electrical connectors 94 may include placing solder on the exposed portions of the UBMs 92 and then reflowing the solder to form solder balls. In some embodiments, the formation of the electrical connectors 94 includes performing a plating step to form solder regions over redistribution wirings 86 and then reflowing the solder regions. In some other embodiments, the electrical connectors 94 include metal pillars or metal pillars and solder caps, which may also be formed through plating. Throughout the description, the combined structure including the chip stacking structure 100, the conductive through vias 72, the insulating encapsulant 76′, the redistribution circuit structure 61, the redistribution circuit structure 77, the UBMs 92 and the electrical connectors 94 will be referred to as a wafer level package, which may be a composite wafer with a round top-view shape.

Referring to FIG. 2H and FIG. 2I, a de-bonding process is then performed such that the carrier 60 is de-bonded from the wafer level package. After performing the de-bonding process, the dielectric layer 64 of the redistribution circuit structure 61 are revealed. During the de-bonding process, the de-bonding layer 62 is also cleaned from the wafer level package. The de-bonding may be performed by irradiating a light such as UV light or laser on the de-bonding layer 62 to decompose the de-bonding layer 62. In the de-bonding process, a tape (not shown) may be adhered onto the dielectric layer 88 and the electrical connectors 94. In subsequent steps, the carrier 60 and the de-bonding layer 62 are removed from the wafer level package. A singulation process is performed to saw the wafer level package illustrated in FIG. 2H into multiple singulated integrated fanout packages P1 illustrated in FIG. 2I.

A patterning process is performed to form openings in the dielectric layer 64 to expose the redistribution wirings 66. The formation of the openings defined in the dielectric layer 64 may be performed through a photolithography process. Then, a top package P2 is provided and bonded with the integrated fanout package P1 (i.e., the bottom package) such that a POP structure is formed. In some embodiments of the present disclosure, the bonding between the top package P2 and the integrated fanout package P1 is performed through electrical connectors (e.g., solder regions) 96, which joins the metal pad portions of the redistribution wirings 66 to the metal pads in the top package P2. An underfill 98 may be formed to fill the gap between the top package P2 and the integrated fanout package P1 such that the electrical connectors 96 are laterally encapsulated by the underfill 98 and reliability of the electrical connectors 96 can be enhanced. In some embodiments, the top package P2 includes semiconductor dies 202, which may be memory dies such as Static Random Access Memory (SRAM) dies, Dynamic Random Access Memory (DRAM) dies, or the like. The memory dies may also be bonded to package substrate 204 in some exemplary embodiments.

In accordance with some embodiments of the disclosure, a structure including a first semiconductor die, second semiconductor dies, a bridge die, and a gap filling material is provided. The first semiconductor die includes integrated circuit regions. The second semiconductor dies are disposed over and electrically connected to the first semiconductor die. The bridge die is disposed over and electrically connected to the first semiconductor die, and the integrated circuit regions are electrically connected to each other through the bridge die. The gap filling material is disposed on the first semiconductor die to laterally encapsulate the bridge die and the second semiconductor dies. In some embodiments, the first semiconductor die includes a first bonding structure, each of the second semiconductor dies includes a second bonding structure, the bridge die includes a third bonding structure, the second bonding structure of each of the second semiconductor dies is in contact with and electrically connected to the first bonding structure, and the third bonding structure is in contact with and electrically connected to the first bonding structure. In some embodiments, the first semiconductor die includes a first semiconductor substrate, a first interconnect structure disposed on the first semiconductor substrate, and a first bonding structure disposed on and electrically connected to the first interconnect structure; each of the second semiconductor dies includes a second semiconductor substrate, a second interconnect structure disposed on the second semiconductor substrate, and a second bonding structure disposed on and electrically connected to the second interconnect structure; the bridge die includes a third semiconductor substrate, a third interconnect structure disposed on the third semiconductor substrate, and a third bonding structure disposed on and electrically connected to the third interconnect structure; the second bonding structure of each of the second semiconductor dies is in contact with and electrically connected to the first bonding structure; and the third bonding structure is in contact with and electrically connected to the first bonding structure. In some embodiments, the first semiconductor die further includes conductive through vias penetrating through the first semiconductor substrate, the first interconnect structure and the first bonding structure are disposed on opposite sides of the first semiconductor substrate, and the first interconnect structure is electrically connected to the first bonding structure through the conductive through vias. In some embodiments, the structure further includes conductive terminals disposed on and electrically connected to the first interconnect structure of the first semiconductor die. In some embodiments, the first bonding structure includes a first bonding dielectric layer and first bonding conductors embedded in the first bonding dielectric layer; the second bonding structure includes a second bonding dielectric layer and second bonding conductors embedded in the second bonding dielectric layer; the third bonding structure includes a third bonding dielectric layer and third bonding conductors embedded in the third bonding dielectric layer, wherein the first bonding conductors are bonded to the second bonding conductors and the third bonding conductors, and the second bonding dielectric layer and third bonding dielectric layer are bonded to portions of the first bonding dielectric layer. In some embodiments, the second semiconductor dies are arranged side-by-side on the first semiconductor die, and the bridge die is disposed between the second semiconductor dies. In some embodiments, the structure further includes a support substrate, wherein the gap filling material, the second semiconductor dies and the bridge die are disposed between the support substrate and the first semiconductor die. In some embodiments, the first semiconductor die further includes a dummy region, and the integrated circuit regions are spaced apart from each other by the dummy region.

In accordance with some other embodiments of the disclosure, a structure including a first semiconductor die, second semiconductor dies, and a bridge die is provided. The first semiconductor die includes a first integrated circuit region and a second integrated circuit region spaced apart from the first integrated circuit region. The second semiconductor dies are disposed over and electrically connected to the first integrated circuit region and the second integrated circuit region. The bridge die is disposed over and electrically connected to the first integrated circuit region and the second integrated circuit region. In some embodiments, the structure further includes a gap filling material laterally encapsulating the bridge die and the second semiconductor dies. In some embodiments, the structure further includes an adhesive layer and a support substrate, wherein the support substrate is adhered to the gap filling material, the second semiconductor dies and the bridge die by the adhesive layer. In some embodiments, sidewalls of the support substrate substantially align with sidewalls of the gap filling material and sidewalls of the first semiconductor die. In some embodiments, the support substrate and the first semiconductor die are substantially identical in lateral dimension. In some embodiments, the second semiconductor dies and the bridge die are substantially identical in thickness.

In accordance with some other embodiments of the disclosure, a structure including a first semiconductor die, second semiconductor dies, and a bridge die is provided. The first semiconductor die includes integrated circuit regions and a bonding structure, wherein the bonding structure covers the integrated circuit regions, and the integrated circuit regions are laterally spaced apart from each other. The second semiconductor dies are disposed over and electrically connected to the integrated circuit regions through the bonding structure. The bridge die is disposed over the bonding structure and electrically connected to the integrated circuit regions through the bonding structure. In some embodiments, the structure further includes a gap filling material laterally encapsulating the bridge die and the second semiconductor dies, wherein the gap filling material, the second semiconductor dies and the bridge die are substantially identical in thickness. In some embodiments, the structure further includes a support substrate, wherein the support substrate is adhered to the gap filling material, the second semiconductor dies and the bridge die. In some embodiments, sidewalls of the support substrate substantially align with sidewalls of the gap filling material and sidewalls of the first semiconductor die. In some embodiments, the first semiconductor die further includes a dummy region located between the integrated circuit regions, the bridge die is disposed over and covers the dummy region, and the integrated circuit regions are spaced apart from each other by the dummy region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
a first semiconductor die comprising integrated circuit regions;
second semiconductor dies disposed over and electrically connected to the first semiconductor die;
a bridge die disposed over and electrically connected to the first semiconductor die, the integrated circuit regions being electrically connected to each other through the bridge die; and
a gap filling layer disposed on the first semiconductor die to laterally encapsulate the bridge die and the second semiconductor dies.

2. The structure of claim 1, wherein the first semiconductor die comprises a first bonding structure, each of the second semiconductor dies comprises a second bonding structure, the bridge die comprises a third bonding structure, the second bonding structure of each of the second semiconductor dies is in contact with and electrically connected to the first bonding structure, and the third bonding structure is in contact with and electrically connected to the first bonding structure.

3. The structure of claim 1, wherein
the first semiconductor die comprises a first semiconductor substrate, a first interconnect structure disposed on the first semiconductor substrate, and a first bonding structure disposed on and electrically connected to the first interconnect structure,
each of the second semiconductor dies comprises a second semiconductor substrate, a second interconnect structure disposed on the second semiconductor substrate, and a second bonding structure disposed on and electrically connected to the second interconnect structure, the bridge die comprises a third semiconductor substrate, a third interconnect structure disposed on the third semiconductor substrate, and a third bonding structure disposed on and electrically connected to the third interconnect structure,
the second bonding structure of each of the second semiconductor dies is in contact with and electrically connected to the first bonding structure, and
the third bonding structure is in contact with and electrically connected to the first bonding structure.

4. The structure of claim 3, wherein the first semiconductor die further comprises conductive through vias penetrating through the first semiconductor substrate, the first interconnect structure and the first bonding structure are disposed on opposite sides of the first semiconductor substrate, and the first interconnect structure is electrically connected to the first bonding structure through the conductive through vias.

5. The structure of claim 3 further comprising conductive terminals disposed on and electrically connected to the first interconnect structure of the first semiconductor die.

6. The structure of claim 2, wherein the first bonding structure comprises a first bonding dielectric layer and first bonding conductors embedded in the first bonding dielectric layer, the second bonding structure comprises a second bonding dielectric layer and second bonding conductors embedded in the second bonding dielectric layer, the third bonding structure comprises a third bonding dielectric layer and third bonding conductors embedded in the third bonding dielectric layer, the first bonding conductors are bonded to the second bonding conductors and the third bonding conductors, and the second bonding dielectric layer and third bonding dielectric layer are bonded to portions of the first bonding dielectric layer.

7. The structure of claim 1, wherein the second semiconductor dies are arranged side-by-side on the first semiconductor die, and the bridge die is disposed between the second semiconductor dies.

8. The structure of claim 1 further comprising:
a support substrate, wherein the gap filling layer, the second semiconductor dies and the bridge die are disposed between the support substrate and the first semiconductor die.

9. The structure of claim 1, wherein the first semiconductor die further comprises a dummy region, and the integrated circuit regions are spaced apart from each other by the dummy region.

10. A structure, comprising:
a first semiconductor die comprising a first integrated circuit region and a second integrated circuit region spaced apart from the first integrated circuit region;
second semiconductor dies disposed over and electrically connected to the first integrated circuit region and the second integrated circuit region; and
a bridge die disposed over and electrically connected to the first integrated circuit region and the second integrated circuit region.

11. The structure of claim 10 further comprising:
a gap filling layer laterally encapsulating the bridge die and the second semiconductor dies.

12. The structure of claim 11 further comprising:
an adhesive layer; and
a support substrate, wherein the support substrate is adhered to the gap filling layer, the second semiconductor dies and the bridge die by the adhesive layer.

13. The structure of claim 12, wherein sidewalls of the support substrate substantially align with sidewalls of the gap filling layer and sidewalls of the first semiconductor die.

14. The structure of claim 12, wherein the support substrate and the first semiconductor die are substantially identical in lateral dimension.

15. The structure of claim 10, wherein the second semiconductor dies and the bridge die are substantially identical in thickness.

16. A structure, comprising:
a first semiconductor die comprising integrated circuit regions and a bonding structure, wherein the bonding structure covers the integrated circuit regions, and the integrated circuit regions are laterally spaced apart from each other;
second semiconductor dies disposed over and electrically connected to the integrated circuit regions through the bonding structure; and
a bridge die disposed over the bonding structure and electrically connected to the integrated circuit regions through the bonding structure.

17. The structure of claim 16 further comprising:
a gap filling layer laterally encapsulating the bridge die and the second semiconductor dies, wherein the gap filling layer, the second semiconductor dies and the bridge die are substantially identical in thickness.

18. The structure of claim 16 further comprising:
a support substrate, wherein the support substrate is adhered to the gap filling layer, the second semiconductor dies and the bridge die.

19. The structure of claim 16, wherein sidewalls of the support substrate substantially align with sidewalls of the gap filling layer and sidewalls of the first semiconductor die.

20. The structure of claim 16, wherein the first semiconductor die further comprises a dummy region located between the integrated circuit regions, the bridge die is disposed over and covers the dummy region, and the integrated circuit regions are spaced apart from each other by the dummy region.
